(19) United States
(12) Patent Application Publication
(10) Pub. No.: US 2021/0217768 A1
(43) Pub. Date: Jul. 15, 2021

(54) Memory Devices and Methods of Forming Memory Devices

(71) Applicant: Micron Technology, Inc., Boise, ID (US)

(72) Inventors: Yoshiaki Fukuzumi, Yokohama (JP); Akira Goda, Tokyo (JP)

(73) Assignee: Micron Technology, Inc., Boise, ID (US)

(21) Appl. No.: 16/743,422

(22) Filed: Jan. 15, 2020

(51) Int. Cl. H01L 27/11582; H01L 27/11573; H01L 23/528; H01L 21/02; H01L 21/768; H01L 21/78; H01L 29/51

(52) U.S. Cl. CPC H01L 27/11582; H01L 27/11573; H01L 23/528; H01L 21/02532; H01L 21/76802; H01L 29/518; H01L 21/76877; H01L 21/7806; H01L 21/02598; H01L 29/513; H01L 21/76831

(57) ABSTRACT

Some embodiments include a method of forming a memory device. An assembly is formed to have channel structures extending through a stack of alternating insulative and conductive levels and into a first material under the stack. The assembly is inverted so that the first material is above the stack, and so that first regions of the channel structures are under the stack. At least some of the first regions are electrically coupled with control circuitry. At least some of the first material is removed, and second regions of the channel structures are exposed. Conductively-doped semiconductor material is formed adjacent the exposed second regions of the channel structures. Dopant is out-diffused from the conductively-doped semiconductor material into the channel structures. Some embodiments include memory devices (e.g., NAND memory assemblies).

### TECHNICAL FIELD

Integrated assemblies (e.g., integrated memory), and methods of forming integrated assemblies.

### BACKGROUND

Memory provides data storage for electronic systems. Flash memory is one type of memory, and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of flash memory, and may be configured to comprise vertically-stacked memory cells.

Before describing NAND specifically, it may be helpful to more generally describe the relationship of a memory array within an integrated arrangement. FIG. 1 shows a block diagram of a prior art device 1000 which includes a memory array 1002 having a plurality of memory cells 1003 arranged in rows and columns along with access lines 1004 (e.g., wordlines to conduct signals WL0 through WLm) and first data lines 1006 (e.g., bitlines to conduct signals BL0 through BLn). Access lines 1004 and first data lines 1006 may be used to transfer information to and from the memory cells 1003. A row decoder 1007 and a column decoder 1008 decode address signals A0 through AX on address lines 1009 to determine which ones of the memory cells 1003 are to be accessed. A sense amplifier circuit 1015 operates to determine the values of information read from the memory cells 1003. An I/O circuit 1017 transfers values of information between the memory array 1002 and input/output (I/O) lines 1005. Signals DQ0 through DQN on the I/O lines 1005 can represent values of information read from or to be written into the memory cells 1003. Other devices can communicate with the device 1000 through the I/O lines 1005, the address lines 1009, or the control lines 1020. A memory control unit 1018 is used to control memory operations to be performed on the memory cells 1003, and utilizes signals on the control lines 1020. The device 1000 can receive supply voltage signals Vcc and Vss on a first supply line 1030 and a second supply line 1032, respectively. The device 1000 includes a select circuit 1040 and an input/output (I/O) circuit 1017. The select circuit 1040 can respond, via the I/O circuit 1017, to signals CSEL1 through CSELn to select signals on the first data lines 1006 and the second data lines 1013 that can represent the values of information to be read from or to be programmed into the memory cells 1003. The column decoder 1008 can selectively activate the CSEL1 through CSELn signals based on the AO through AX address signals on the address lines 1009. The select circuit 1040 can select the signals on the first data lines 1006 and the second data lines 1013 to provide communication between the memory array 1002 and the I/O circuit 1017 during read and programming operations.

The memory array 1002 of FIG. 1 may be a NAND memory array, and FIG. 2 shows a schematic diagram of a three-dimensional NAND memory device 200 which may be utilized for the memory array 1002 of FIG. 1. The device 200 comprises a plurality of strings of charge-storage devices. In a first direction (Z-Z′), each string of charge-storage devices may comprise, for example, thirty-two charge-storage devices stacked over one another with each charge-storage device corresponding to one of, for example, thirty-two tiers (e.g., Tier0-Tier31). The charge-storage devices of a respective string may share a common channel region, such as one formed in a respective pillar of semiconductor material (e.g., polysilicon) about which the string of charge-storage devices is formed. In a second direction (X-X′), each first group of, for example, sixteen first groups of the plurality of strings may comprise, for example, eight strings sharing a plurality (e.g., thirty-two) of access lines (i.e., “global control gate (CG) lines”, also known as wordlines, WLs). Each of the access lines may couple the charge-storage devices within a tier. The charge-storage devices coupled by the same access line (and thus corresponding to the same tier) may be logically grouped into, for example, two pages, such as P0/P32, P1/P33, P2/P34 and so on, when each charge-storage device comprises a cell capable of storing two bits of information. In a third direction (Y-Y′), each second group of, for example, eight second groups of the plurality of strings, may comprise sixteen strings coupled by a corresponding one of eight data lines. The size of a memory block may comprise 1,024 pages and total about 16 MB (e.g., 16 WLs×32 tiers×2 bits=1,024 pages/block, block size=1,024 pages×16 KB/page=16 MB). The number of the strings, tiers, access lines, data lines, first groups, second groups and/or pages may be greater or smaller than those shown in FIG. 2.

FIG. 3 shows a cross-sectional view of a memory block 300 of the 3D NAND memory device 200 of FIG. 2 in an X-X′ direction, including fifteen strings of charge-storage devices in one of the sixteen first groups of strings described with respect to FIG. 2. The plurality of strings of the memory block 300 may be grouped into a plurality of subsets 310, 320, 330 (e.g., tile columns), such as tile column_{I}, tile columnⱼ and tile column_{K}, with each subset (e.g., tile column) comprising a “partial block” (sub-block) of the memory block 300. A global drain-side select gate (SGD) line 340 may be coupled to the SGDs of the plurality of strings. For example, the global SGD line 340 may be coupled to a plurality (e.g., three) of sub-SGD lines 342, 344, 346 with each sub-SGD line corresponding to a respective subset (e.g., tile column), via a corresponding one of a plurality (e.g., three) of sub-SGD drivers 332, 334, 336. Each of the sub-SGD drivers 332, 334, 336 may concurrently couple or cut off the SGDs of the strings of a corresponding partial block (e.g., tile column) independently of those of other partial blocks. A global source-side select gate (SGS) line 360 may be coupled to the SGSs of the plurality of strings. For example, the global SGS line 360 may be coupled to a plurality of sub-SGS lines 362, 364, 366 with each sub-SGS line corresponding to the respective subset (e.g., tile column), via a corresponding one of a plurality of sub-SGS drivers 322, 324, 326. Each of the sub-SGS drivers 322, 324, 326 may concurrently couple or cut off the SGSs of the strings of a corresponding partial block (e.g., tile column) independently of those of other partial blocks. A global access line (e.g., a global CG line) 350 may couple the charge-storage devices corresponding to the respective tier of each of the plurality of strings. Each global CG line (e.g., the global CG line 350) may be coupled to a plurality of sub-access lines (e.g., sub-CG lines) 352, 354, 356 via a corresponding one of a plurality of sub-string drivers 312, 314 and 316. Each of the sub-string drivers may concurrently couple or cut off the charge-storage devices corresponding to the respective partial block and/or tier independently of those of other partial blocks and/or other tiers. The charge-storage devices corresponding to the respective subset (e.g., partial block) and the respective tier may comprise a “partial tier” (e.g., a single “tile”) of charge-storage devices. The strings corresponding to the respective subset (e.g., partial block) may be coupled to a corresponding one of sub-sources 372, 374 and 376 (e.g., “tile source”) with each sub-source being coupled to a respective power source.

The NAND memory device 200 is alternatively described with reference to a schematic illustration of FIG. 4.

The memory array 200 includes wordlines 202₁ to 202_{N}, and bitlines 228₁ to 228_{M}.

The memory array 200 also includes NAND strings 206₁ to 206_{M}. Each NAND string includes charge-storage transistors 208₁ to 208_{N}. The charge-storage transistors may use floating gate material (e.g., polysilicon) to store charge, or may use charge-trapping material (such as, for example, silicon nitride, metallic nanodots, etc.) to store charge.

The charge-storage transistors 208 are located at intersections of wordlines 202 and strings 206. The charge-storage transistors 208 represent non-volatile memory cells for storage of data. The charge-storage transistors 208 of each NAND string 206 are connected in series source-to-drain between a source-select device (e.g., source-side select gate, SGS) 210 and a drain-select device (e.g., drain-side select gate, SGD) 212. Each source-select device 210 is located at an intersection of a string 206 and a source-select line 214, while each drain-select device 212 is located at an intersection of a string 206 and a drain-select line 215. The select devices 210 and 212 may be any suitable access devices, and are generically illustrated with boxes in FIG. 4.

A source of each source-select device 210 is connected to a common source line 216. The drain of each source-select device 210 is connected to the source of the first charge-storage transistor 208 of the corresponding NAND string 206. For example, the drain of source-select device 210₁ is connected to the source of charge-storage transistor 208₁ of the corresponding NAND string 206₁. The source-select devices 210 are connected to source-select line 214.

The drain of each drain-select device 212 is connected to a bitline (i.e., digit line) 228 at a drain contact. For example, the drain of drain-select device 212₁ is connected to the bitline 228₁. The source of each drain-select device 212 is connected to the drain of the last charge-storage transistor 208 of the corresponding NAND string 206. For example, the source of drain-select device 212₁ is connected to the drain of charge-storage transistor 208_{N} of the corresponding NAND string 206₁.

The charge-storage transistors 208 include a source 230, a drain 232, a charge-storage region 234, and a control gate 236. The charge-storage transistors 208 have their control gates 236 coupled to a wordline 202. A column of the charge-storage transistors 208 are those transistors within a NAND string 206 coupled to a given bitline 228. A row of the charge-storage transistors 208 are those transistors commonly coupled to a given wordline 202.

The vertically-stacked memory cells of three-dimensional NAND architecture may be block-erased by generating hole carriers beneath them, and then utilizing an electric field to sweep the hole carriers upwardly along the memory cells.

Gating structures of transistors may be utilized to provide gate-induced drain leakage (GIDL) which generates the holes utilized for block-erase of the memory cells. The transistors may be the source-side select (SGS) devices described above. The channel material associated with a string of memory cells may be configured as a channel material pillar, and a region of such pillar may be gatedly coupled with an SGS device. The gatedly coupled portion of the channel material pillar is a portion that overlaps a gate of SGS device.

It can be desired that at least some of the gatedly coupled portion of the channel material pillar be heavily doped. In some applications it can be desired that the gatedly coupled portion include both a heavily-doped lower region and a lightly-doped upper region; with both regions overlapping the gate of the SGS device. Specifically, overlap with the lightly-doped region provides a non-leaky “OFF” characteristic for the SGS device, and overlap with the heavily-doped region provides leaky GIDL characteristics for the SGS device. The terms “heavily-doped” and “lightly-doped” are utilized in relation to one another rather than relative to specific conventional meanings. Accordingly, a “heavily-doped” region is more heavily doped than an adjacent “lightly-doped” region, and may or may not comprise heavy doping in a conventional sense. Similarly, the “lightly-doped” region is less heavily doped than the adjacent “heavily-doped” region, and may or may not comprise light doping in a conventional sense. In some applications, the term “lightly-doped” refers to semiconductor material having less than or equal to about 10¹⁸ atoms/cm³ of dopant, and the term “heavily-doped” refers to semiconductor material having greater than or equal to about 10¹⁹ atoms/cm³ of dopant.

The channel material may be initially doped to the lightly-doped level, and then the heavily-doped region may be formed by out-diffusion from an underlying doped semiconductor material.

It is desired to develop improved methods of forming memory devices (e.g., NAND memory assemblies), and to develop improved memory devices.

### BRIEF DESCRIPTION OF THE DRAWINGS

FIG. 1 shows a block diagram of a prior art memory device having a memory array with memory cells.

FIG. 2 shows a schematic diagram of the prior art memory device of FIG. 1 in the form of a 3D NAND memory device.

FIG. 3 shows a cross-sectional view of the prior art 3D NAND memory device of FIG. 2 in an X-X′ direction.

FIG. 4 is a schematic diagram of a prior art NAND memory array.

FIG. 5 shows diagrammatic cross-sectional side views of regions of example integrated assemblies at an example process stage of an example method.

FIG. 6 is a diagrammatic cross-sectional side view of the regions of FIG. 5 at an example process stage following the process stage of FIG. 5.

FIG. 7 is a diagrammatic cross-sectional side view of the regions of FIG. 5 at an example process stage following the process stage of FIG. 6.

FIGS. 7A, 7B and 7C are diagrammatic cross-sectional side views of portion of the configuration of FIG. 7 showing example configurations of one of the illustrated structures.

FIG. 8 is a diagrammatic cross-sectional side view of the regions of FIG. 5 at an example process stage following the process stage of FIG. 7, and shows an example memory device.

FIGS. 9 and 10 are diagrammatic cross-sectional side views of a region of an example integrated assembly at example sequential process stages of an example method.

FIG. 10A is a diagrammatic cross-sectional side view of a region of an example integrated assembly alternative to the assembly of FIG. 10.

FIGS. 11-16 are diagrammatic cross-sectional side views of the region of the example integrated assembly of FIGS. 9 and 10 at example sequential process stages following the process stage of FIG. 10.

FIG. 16A is a diagrammatic cross-sectional side view of the region of the example integrated assembly of FIGS. 9 and 10 at an example process stage alternative to that of FIG. 16.

FIG. 17 is a diagrammatic cross-sectional side view of the region of the example integrated assembly of FIGS. 9 and 10 at an example process stage following the process stage of FIG. 16.

FIG. 17A is a diagrammatic cross-sectional side view of the region of the example integrated assembly of FIGS. 9 and 10 at an example process stage alternative to that of FIG. 16.

FIGS. 18-20 are diagrammatic cross-sectional side views of the region of the example integrated assembly of FIGS. 9 and 10 at example sequential process stages following the process stage of FIG. 17. An example memory device is illustrated in FIG. 20.

FIGS. 21-24 are diagrammatic cross-sectional side views of a region of an example integrated assembly at example sequential process stages of an example method.

### DETAILED DESCRIPTION OF THE ILLUSTRATED EMBODIMENTS

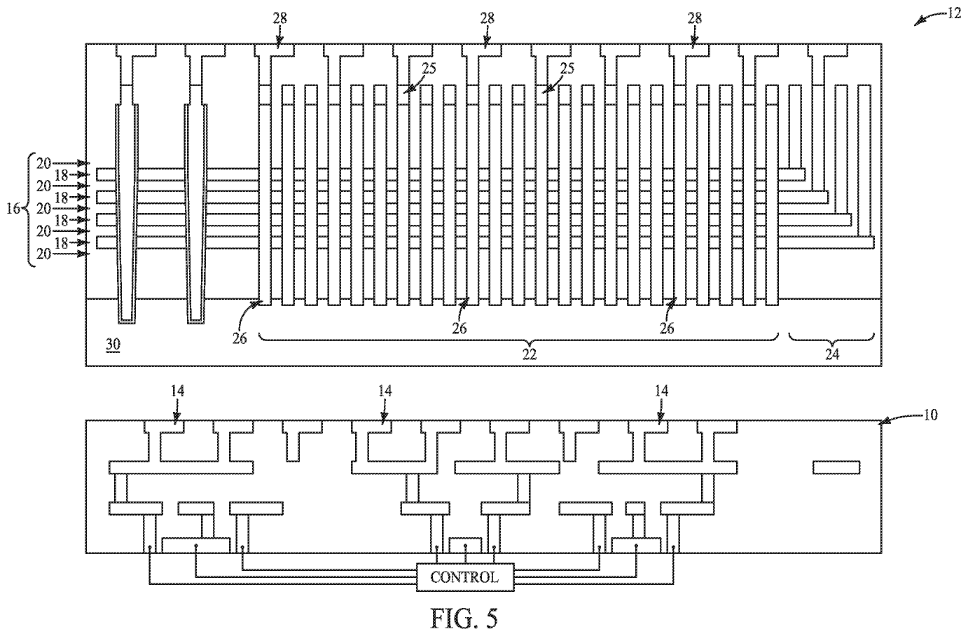

Some embodiments include methods of forming memory devices (e.g., NAND memory architectures) in which an assembly comprising stacked conductive levels is bonded to another assembly comprising control circuitry. The stacked conductive levels are spaced from one another by intervening insulative levels. Channel structures extend through the stacked conductive levels, and at least some of the channel structures may be electrically coupled with the control circuitry through bitlines. Memory cells are along at least some of the stacked conductive levels. A source structure is formed over the channel structures, and is electrically coupled with the channel structures. Some embodiments include memory devices. Example embodiments are described with reference to FIGS. 5-24.

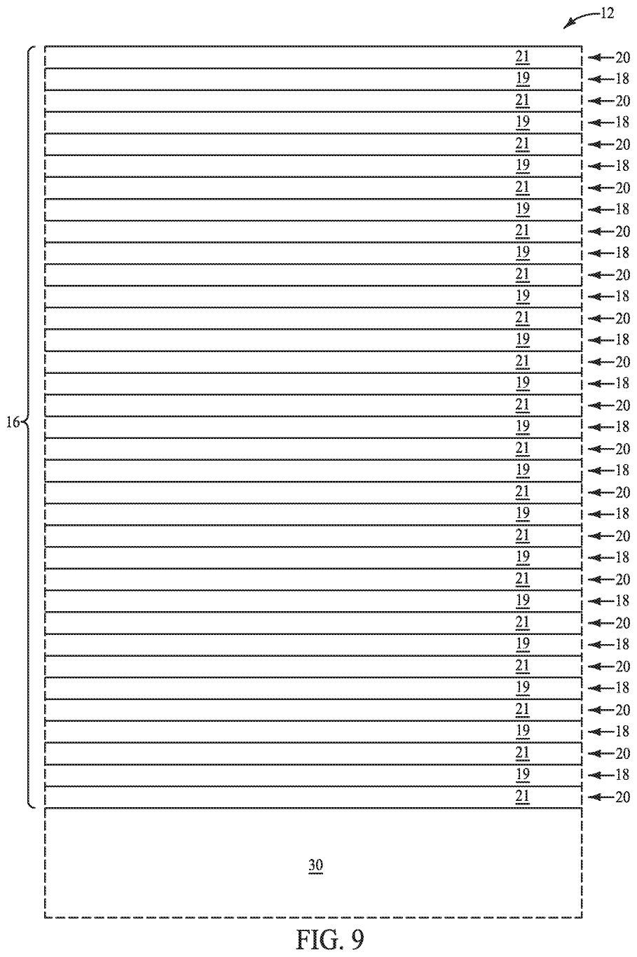

An overview of an example method is described with reference to FIGS. 5-8, and more detailed descriptions of the example method are provided relative to FIGS. 9-24. Conductive materials are not shown with cross-hatching in FIGS. 5-8 in order to simplify the drawings, but are shown with cross-hatching in FIGS. 9-24.

Referring to FIG. 5, a pair of integrated assemblies 10 and 12 are illustrated. The assemblies 10 and 12 may be referred to as first and second assemblies, respectively.

The first assembly 10 comprises electrical connections 14 (only some of which are labeled), with at least some of the connections being electrically coupled with control circuitry (CONTROL). The control circuitry may comprise, for example, CMOS (complementary metal-oxide-semiconductor) devices. In some embodiments, the first assembly 10 may be considered to comprise the control circuitry in addition to comprising the electrical connections 14.

The electrical connections 14 may comprise any suitable electrically conductive composition(s); such as, for example, one or more of various metals (e.g., copper, titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.). In some embodiments, the interconnects 14 may comprise, consist essentially of, or consist of copper.

The second assembly 12 includes a stack 16 of alternating conductive levels (first levels) 18, and insulative levels (second levels) 20.

The conductive levels 18 may comprise any suitable electrically conductive composition(s); such as, for example, one or more of various metals (e.g., titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.). In some embodiments, the conductive levels may comprise a tungsten core at least partially surrounded by a liner comprising titanium nitride.

The insulative levels 20 may comprise any suitable composition(s); and in some embodiments may comprise, consist essentially of, or consist of silicon dioxide.

Although only four conductive levels 18 are shown in order to simplify the drawing, it is to be understood that there may be more than the four illustrated conductive levels. In some embodiments, at least some of the conductive levels 18 may correspond to wordline levels/memory cell levels of a memory array (e.g., a memory array associated with NAND memory). In such embodiments, there may be any suitable number of the wordline levels/memory cell levels, including, for example, eight levels, 16 levels, 32 levels, 64 levels, 128 levels, etc.

The assembly 12 includes a memory array region 22, and an interconnect region (staircase region) 24 adjacent to the memory array region. The staircase region may be utilized for establishing interconnects to the individual conductive levels 18, as shown.

The assembly 12 includes channel structures 26 (only some of which are labeled). The channel structures extend through the stack 16.

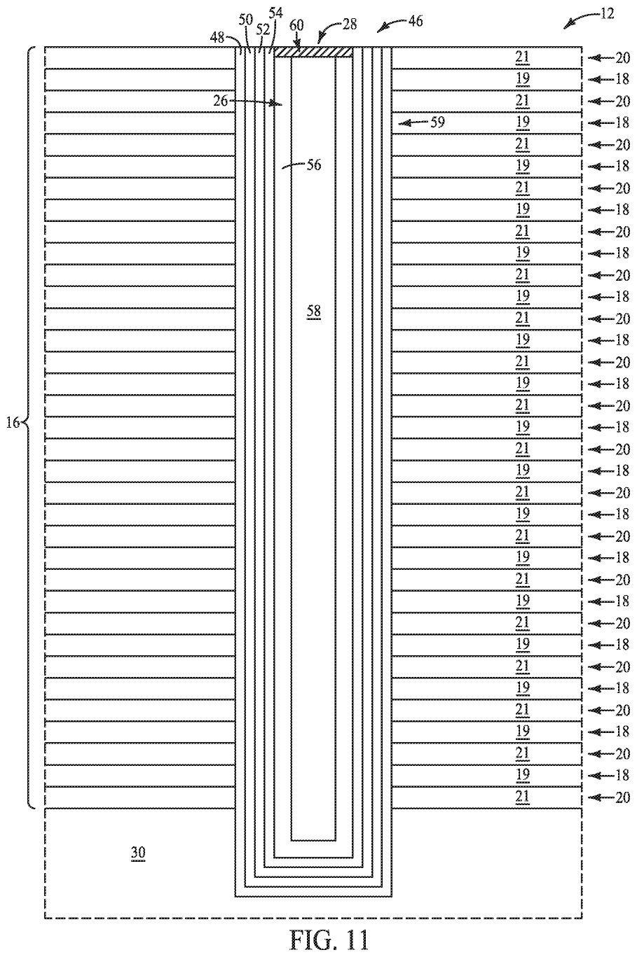

The channel structures may comprise any suitable configurations, with example configurations been described in more detail below with reference to FIG. 11.

At least some of the channel structures are electrically coupled with conductive interconnects 28 (only some which are labeled). The interconnects 28 may comprise any suitable material; including, for example, one or more of the materials described above with respect to the interconnects 14. In some embodiments, the interconnects 14 and 28 may both comprise, consist essentially of, or consist of copper. The connections between the memory pillars 26 and the pads 28 may route through bitlines 25 (which may be considered to be diagrammatically represented by the rectangles over the pillars 26, with such rectangles being between the pads 28 and the pillars 26).

A material 30 is under the stack 16, and the channel structures 26 extend into such material. In some embodiments, the material 30 may be referred to as a first material. The material 30 may be comprised by a semiconductor wafer (e.g. a monocrystalline silicon wafer) in some embodiments. For instance, some embodiments may include wafer to wafer (or wafer on wafer) processing, and the material 30 may correspond to a portion of one of the wafers. Some of the embodiments herein refer to assemblies. It is to be understood that the term “assembly” may refer to a structure bonded to semiconductor wafer (e.g., a silicon wafer), a structure bonded to a chip having integrated circuitry associated therewith, etc. In some applications, a semiconductor wafer may be referred to as a “substrate”, “base”, etc.

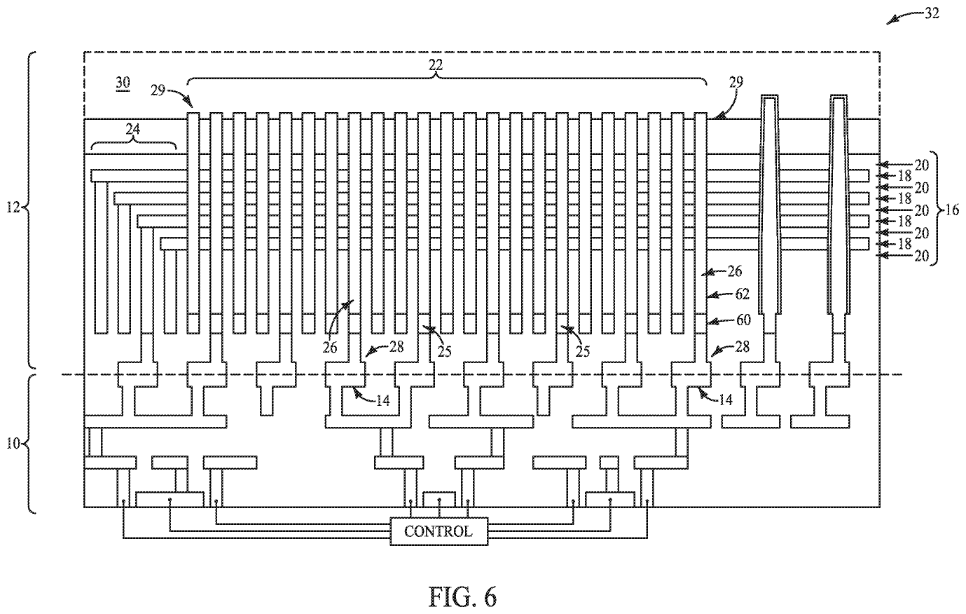

Referring to FIG. 6, the assembly 12 is inverted and bonded to the assembly 10. The combined assemblies 10 and 12 form a third assembly 32. The third assembly 32 has the stack 16 over the control circuitry (CONTROL). The interconnects 28 are bonded with the interconnects 14 to couple at least some of the channel structures 26 with the control circuitry. The connections between the memory pillars 26 and the pads 28 may route through the bitlines (diagrammatically represented by the rectangles 25 between the pillars 26 and the pads 28). In some embodiments, the channel structures 26 may be considered to be electrically coupled to the pads 28 through bitlines (or bitline structures, bitline materials, bitline layers, etc.). Every pillar is generally connected to a bitline and then the control circuit, but only some of such connections are shown in the diagrammatic illustrations provided herewith to simplify the drawings.

The material 30 is shown with a dashed-line periphery to indicate that such material is removed from over a top surface of the assembly 32 after the assemblies 10 and 12 are bonded to one another. In the illustrated embodiment, an entirety of the material 30 is removed. In other embodiments only some of the material 30 may be removed. The removal of the material 30 exposes upper regions 29 of the channel structures 26.

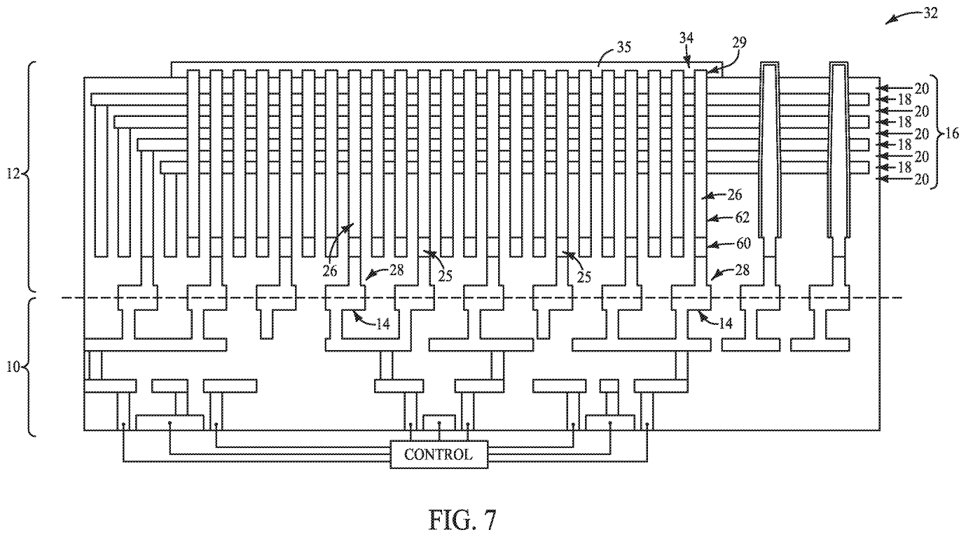

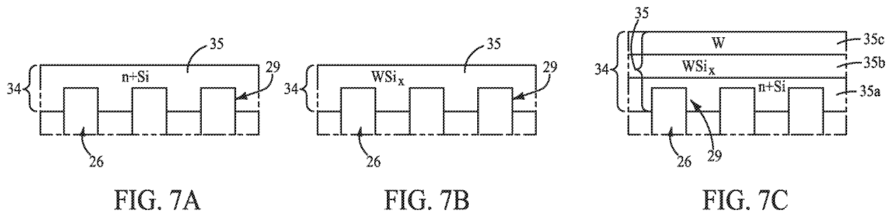

Referring to FIG. 7, a conductive structure 34 is formed over and directly against the exposed regions 29 of the channel structures 26. The conductive structure 34 comprises conductive material 35. The conductive material 35 may comprise semiconductor material; and in some embodiments may comprise, consist essentially of, or consist of one or more of silicon, germanium, III/V semiconductor material (e.g., gallium phosphide), semiconductor oxide, etc.; with the term III/V semiconductor material referring to semiconductor materials comprising elements selected from groups III and V of the periodic table (with groups III and V being old nomenclature, and now being referred to as groups 13 and 15). In some embodiments, the semiconductor material 35 of the structure 34 may comprise, consist essentially of, or consist of silicon. FIGS. 7A-7C show example configurations of the structure 34, and show that such structure may comprise metal (e.g., tungsten (W)), metal-containing material (e.g., WSiₓ, where x is a number greater than 0), and/or doped semiconductor material (e.g., n+ silicon). The embodiment of FIG. 7C shows the material 35 of the structure 34 comprising three compositions 35a, 35b and 35c.

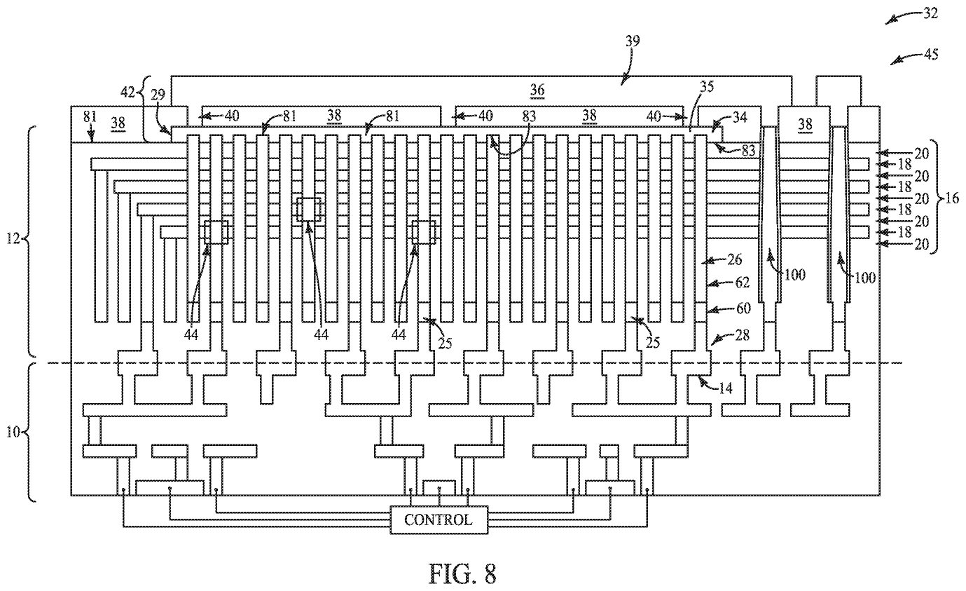

Referring to FIG. 8, a metal-containing material 36 is provided over the structure 34, and is electrically coupled with the structure 34. In the illustrated embodiment, an insulative material 38 is initially provided over the structure 34, and conductive interconnects 40 are provided to extend through the insulative material 38 to contact the conductive material 35 of the structure 34. Subsequently, the metal-containing material 36 is formed over the insulative material 38, and in contact with the conductive interconnects 40.

The metal-containing material 36 may comprise any suitable composition(s). For example, the metal-containing material 36 may comprise, consist essentially of, or consist of one or more titanium, tungsten, cobalt, nickel, platinum, ruthenium, etc.; and/or one or more of metal silicide, metal nitride, metal carbide, etc. In some embodiments, the metal-containing material 36 may comprise tungsten and silicon (e.g., WSiₓ, where x is a number greater than zero). In some embodiments, the metal-containing material 36 may comprise one or both of aluminum and copper. In some embodiments, the metal-containing material 36 may comprise, consist essentially of, or consist of AlCu, where the chemical formula indicates primary constituents rather than a specific stoichiometry. In some embodiments, the structure comprising material 36 is configured as a shunt line relative to the source plate 34. The material 36 may be considered to be comprised by a conductive structure (global interconnect, shunt line, etc.) 39.

The insulative material 38 may comprise any suitable composition(s); and in some embodiments may comprise, consist essentially of, or consist of silicon dioxide.

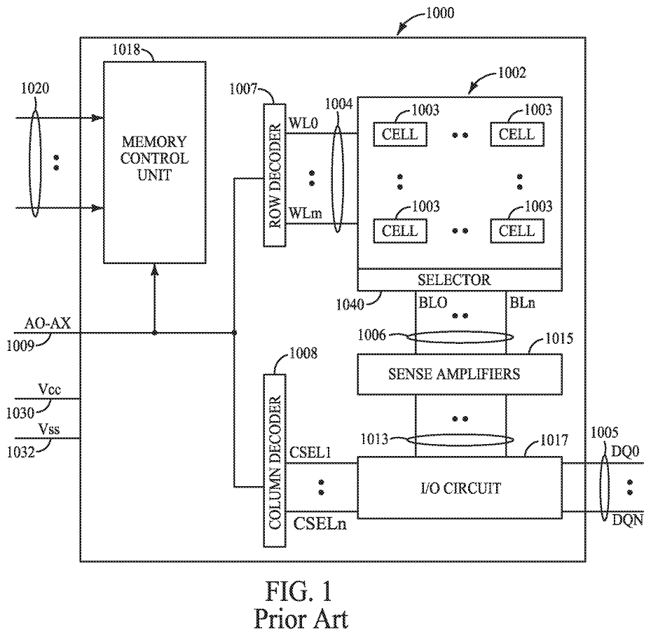

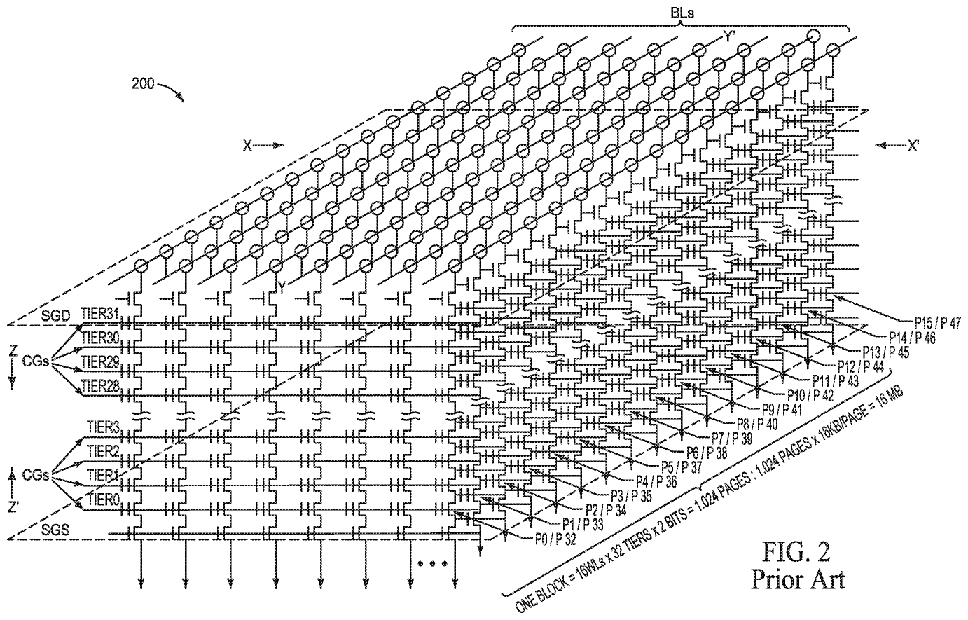

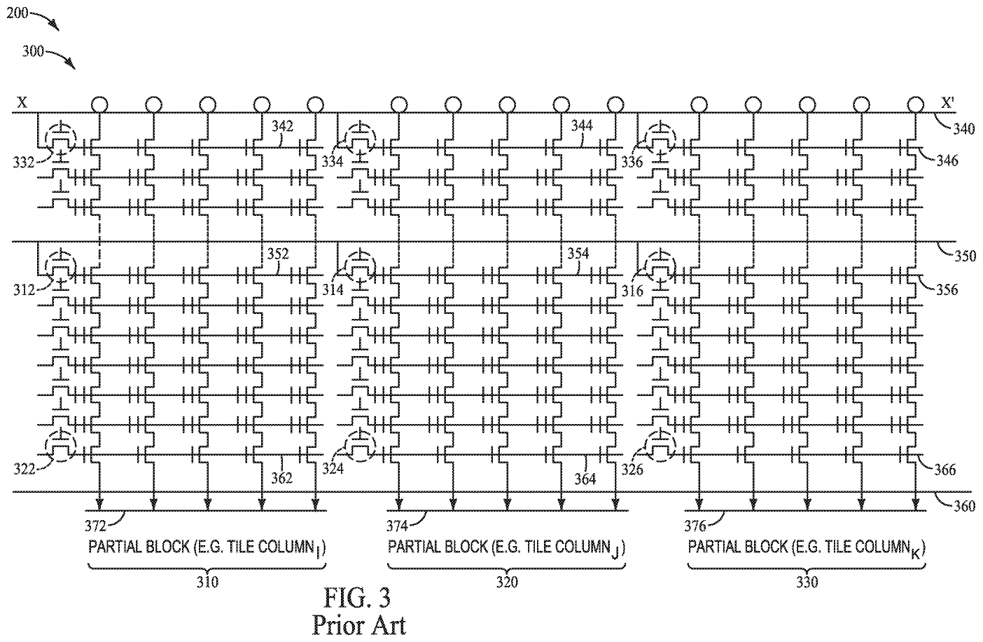

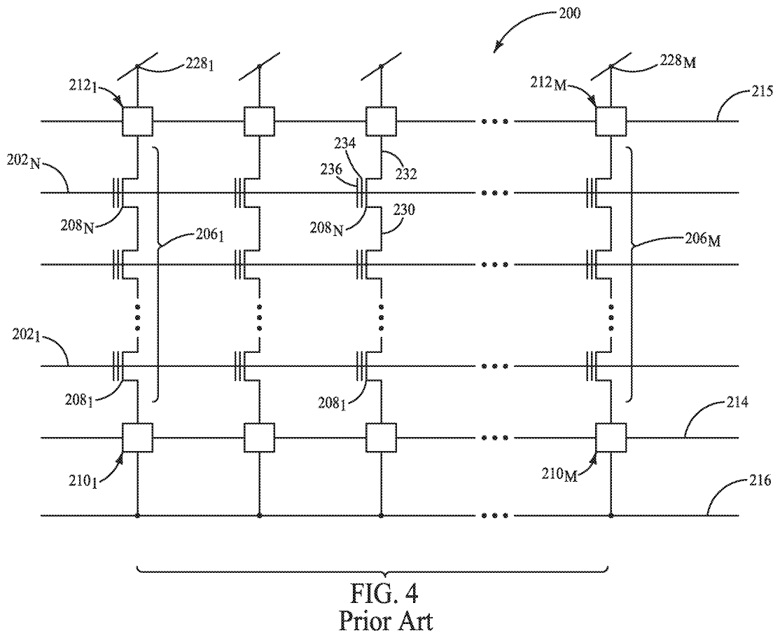

The structures 34 and 39 may be considered together to comprise a source structure 42 analogous to the source structures described above with reference to FIGS. 1-4 (e.g., the source structures 216). The source structure may be electrically coupled with any suitable electrical source (not shown). In some embodiments, the source structure may be biased to around 20 volts (V) during an erase operation, and may maintained at a voltage within a range of from about 0 V to about 2V during read/write operations. In some embodiments, the structure 39 may be considered to be global routing, and the structure 34 may be a bonding pad (a wiring, a wire bonding pad, etc.). In some embodiments, the structure 34 may be considered to be the source structure, and the structure may be considered to be global routing coupled with the source structure.

The configuration of FIG. 8 may be considered to include a memory device 45. The memory device includes memory cells 44 along the conductive levels 18, with only some of the memory cells 44 being shown. The memory cells 44 may be analogous to the memory cells described above with reference to FIGS. 1-4 as being suitable for utilization in NAND memory. Regions of the conductive levels may be incorporated into control gates of the memory structures 44, and other regions of the conductive levels may become wordlines (routing structures) which couple the control gates with other circuitry (e.g., wordline driver circuitry and/or other suitable control circuitry).

The uppermost conductive level 18 within the stack 16 may be a source-side select gate level, and may comprise SGS devices analogous to those described above with reference to FIGS. 1-4.

The processing of FIGS. 5-8 advantageously forms the source structure 34 after fabrication of the channel structures 26. In contrast, conventional methods will generally form a source structure first, will form openings through a stack (analogous to the stack 16) to the source structure, and will then form channel structures (analogous to the structures 26) within the openings. A continuing goal is to increase the number of conductive levels within a stack (analogous to the stack 16) to enable a corresponding increase in the number of wordline/control gate levels. It becomes increasingly problematic to form openings through the stacks and into underlying source structures as the stacks becoming increasingly taller. However, the processing of FIGS. 5-8 enables the source structure to be formed over the channel structures, eliminating the problematic processing associated with conventional methods.

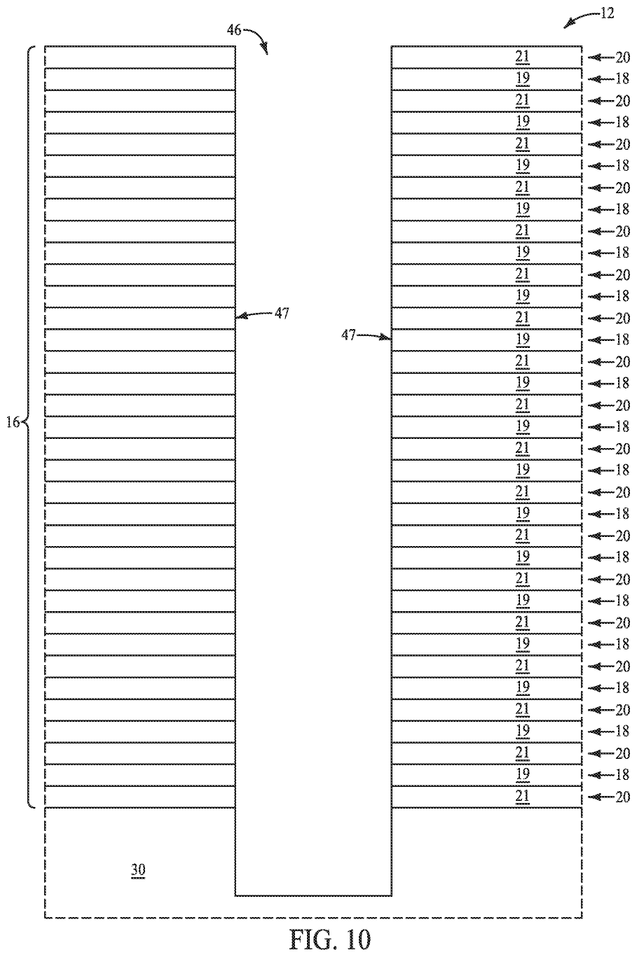

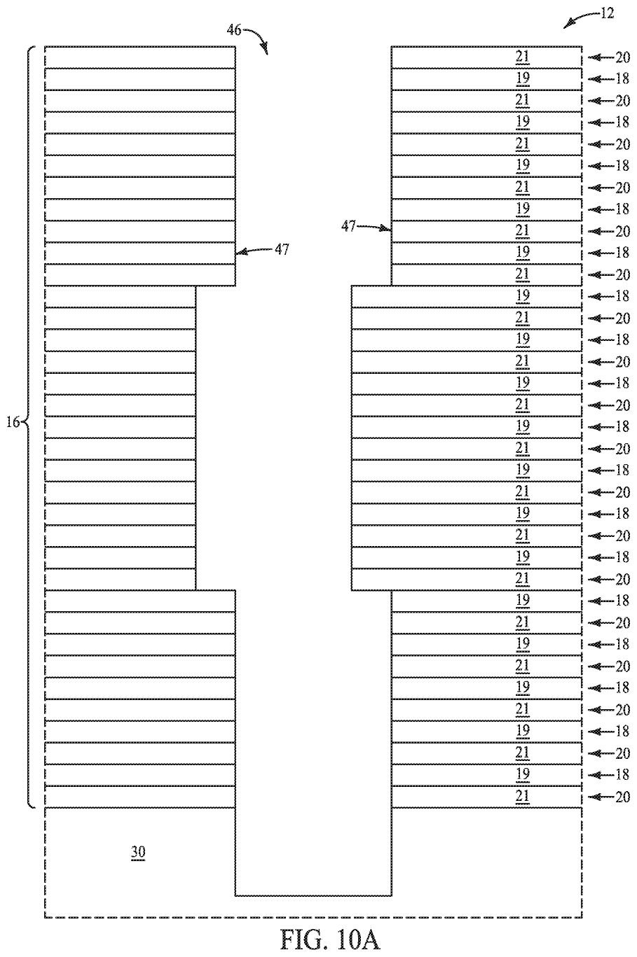

Another advantage of this invention may be its elimination of a conventional bottom punch etch. In the case of bottom punch etch, the channel to source contact may be realized in the following way. After cell films (charge-blocking oxide˜tunneling oxide) are deposited, a sacrificial silicon liner is deposited to the sidewall of cell films to protect the tunneling oxide from etch damage, and an anisotropic punch etch is performed to remove cell films at the bottom part. Then, after diluted HF treatment for native oxide removal at the source silicon surface, the sacrificial silicon liner is removed by an organic alkali etch, and subsequently channel silicon is deposited. The aspect ratio of punch etch may be very high with cell films and liner silicon inside, and it would be much worse in the case of multi-deck process as described in FIG. 10A. At the corners of the inter-deck portion, liner silicon may be easily damaged by the punch-etch, which may lead to wordline leakage. This invention may avoid such issues by forming the source contact from the bottom side of the pillar.

FIGS. 9-24 describe the process of FIGS. 5-8 in additional detail.

Referring to FIG. 9, the assembly 12 includes the stack 16 of the first and second levels 18 and 20. The levels 18 comprise a first material 19, and the levels 20 comprise a second material 21.

The first material 19 may be a sacrificial material; and in some embodiments may comprise, consist essentially of, or consist of silicon nitride. The illustrated material 19 is not conductive, and accordingly the levels 18 are not conductive levels at the process stage of FIG. 9.

The second material 21 is an insulative material; and in some embodiments may comprise, consist essentially of, or consist of silicon dioxide.

The stack 16 is supported by the material 30. The material 30 may be referred to as a third material to distinguish it from the first and second materials 19 and 21. Alternatively, the material 30 may be referred to as a first material, and the materials 19 and 21 may be referred to as second and third materials, respectively.

The material 30 may comprise any suitable composition(s); and in some embodiments may comprise, consist essentially of, or consist of silicon.

Referring to FIG. 10, an opening 46 is formed to extend through the stack 16 and into the material 30. The opening 46 comprises sidewalls 47 along the materials 19 and 21 of the stack 16. In the illustrated embodiment of FIG. 10, the sidewalls 47 are formed to extend substantially straight and vertically (with the term “substantially straight and vertically” meaning straight and vertically to within reasonable tolerances of fabrication and measurement). In other embodiments, the sidewalls 47 may have other configurations. For instance, the stack 16 may comprise multiple decks which are fabricated with multiple punch-through edges, and the sidewalls 47 may have an undulating topography reflecting the stacking of the multiple decks. FIG. 10A shows an embodiment analogous to that of FIG. 10 in an example configuration in which the sidewalls 47 have an undulating topography. FIGS. 11-20 will be based on the configuration of FIG. 10, but it is to be understood that the opening 46 may have any suitable configuration (including, for example, a configuration analogous that of FIG. 10A) in various applications of the embodiments described.

Referring to FIG. 11, dielectric-barrier material 48, charge-blocking material 50, charge-storage material 52, tunneling material (gate-dielectric material) 54 and channel material 56 are formed within the opening 46. The materials 48, 50, 52, 54 and 56 may be together referred to as memory cell materials. The channel material 56 may be considered to be configured as a channel structure 26. It is noted that the dielectric-barrier material 48 may be part of a pillar comprising the material comprising the channel material 56 (as shown in FIG. 11), or may instead be formed along the levels 18 during a so-called gate replacement process. For instance, voids along the levels 18 may be lined with alumina (AlO, where the formula indicates primary constituents rather than a specific stoichiometry), followed by filling of the lined voids with conductive material (for instance, sequential deposition of titanium nitride and tungsten).

The dielectric-barrier material 48 may comprise any suitable composition(s); and in some embodiments may comprise one or more of aluminum oxide, hafnium oxide, zirconium oxide, etc.

The charge-blocking material 50 may comprise any suitable composition(s); and in some embodiments may comprise one or more of silicon dioxide, aluminum oxide, hafnium oxide, zirconium oxide, etc.

The charge-storage material 52 may comprise any suitable composition(s); and in some embodiments may comprise charge-trapping material; such as, for example, one or more of silicon nitride, silicon oxynitride, conductive nanodots, etc.

The tunneling material 54 may comprise any suitable composition(s); and in some embodiments may comprise one or more of silicon dioxide, aluminum oxide, hafnium oxide, zirconium oxide, etc. In some embodiments, the material 54 comprises a laminate containing discrete layers of silicon dioxide and silicon nitride.

The channel material 56 may comprise any suitable composition(s); and in some embodiments may comprise, consist essentially of, or consist of one or more of silicon, germanium, III/V semiconductor material (e.g., gallium phosphide), semiconductor oxide, etc.; with the term III/V semiconductor material referring to semiconductor materials comprising elements selected from groups III and V of the periodic table (with groups III and V being old nomenclature, and now being referred to as groups 13 and 15). In some example embodiments, the channel material 56 may comprise, consist essentially of, or consist of appropriately-doped silicon. The channel material may be configured as an annular ring when viewed from above.

In the illustrated embodiment, the annular-ring-shaped channel material surrounds an insulative material 58 (e.g., silicon dioxide). Such configuration of the channel material may be considered to correspond to a “hollow” channel configuration (or as a hollow channel material pillar), with the dielectric material 58 being provided within the hollow of the channel material configuration. In other embodiments, the channel material may be configured as a solid pillar.

The memory cell materials 48, 50, 52, 54 and 56 may be considered to be configured as a pillar 59 which passes through the stack 16. Such pillar may be representative of a plurality of substantially identical pillars that may be formed at the process stage of FIG. 11. The channel structure 26 may be considered to be a channel-material-pillar, with the channel-material-pillar being an inner region of the memory-cell-material pillar 59.

The channel material 56 and the dielectric material 58 are recessed relative to a top of the opening 46, and a conductive cap 60 is formed over the recessed materials 56 and 58. The cap 60 may comprise any suitable electrically conductive composition(s); such as, for example, one or more of various metals (e.g., titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.). In some example embodiments, the cap 60 may comprise metal-containing material. For instance, the cap 60 may comprise one or more of metal nitride, metal silicide, metal carbide, etc.; such as, for example, one or more of titanium nitride, titanium silicide, tungsten nitride, etc. The cap 60 may be considered to be configured as a conductive interconnect 28 of the type described above with reference to FIG. 5.

An n+ diffusion layer (not shown) may be formed between the cap 60 and the silicon of the channel material 56. This can be done by, for example; recessing material 58, depositing n+-doped silicon, planarization, interlayer dielectric (ILD) deposition and shallow metal plug formation of cap 60. Alternatively, material 58 could be recessed, n+ dopant (phosphorous or arsenic) could be implanted into silicon 56, then the metal material of cap 60 could be deposited and planarized.

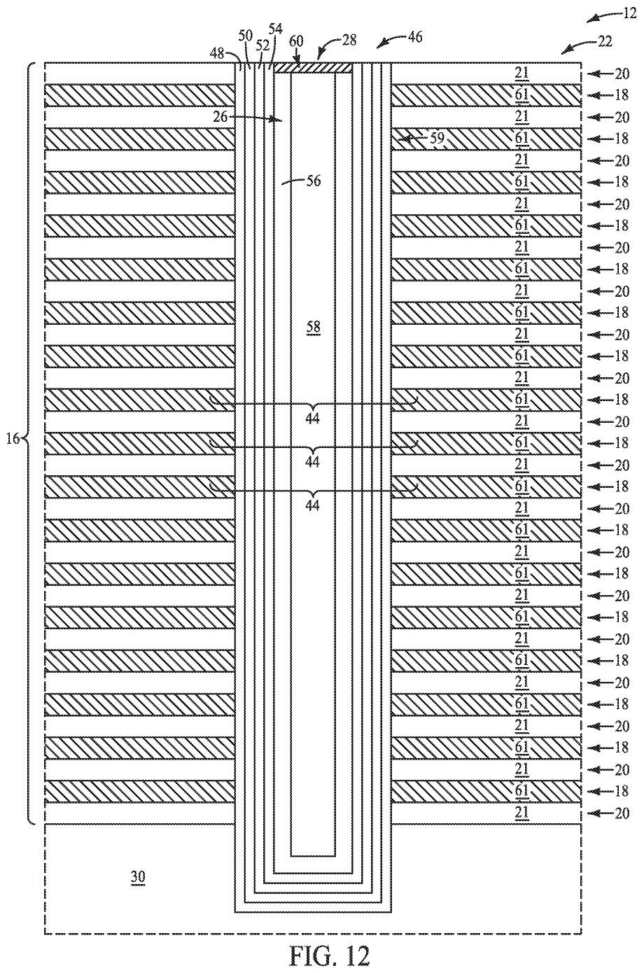

Referring to FIG. 12, the sacrificial material 19 (FIG. 11) is removed and replaced with conductive material 61. Such removal may utilize slits (not shown) formed in the stacked structure 16, with such slits separating blocks and providing access for removal of material 19 to form voids along levels 18, and providing access for deposition of replacement materials within the voids. As discussed above, in some embodiments, dielectric-barrier material 48 may be provided along the levels 18 in addition to the conductive material 61.

The conductive material 61 may comprise any suitable composition(s); and in some embodiments may comprise a tungsten-containing core which is at least partially surrounded by a liner comprising titanium nitride. Although the conductive material 61 is shown to entirely fill the first levels 18, in other embodiments at least some of the material provided within the first levels 18 may be insulative material (e.g., dielectric-barrier material).

The first levels 18 of FIG. 12 correspond to conductive levels analogous to those described above with reference to FIG. 5, and the second levels 20 correspond to insulative levels analogous to those described above with reference to FIG. 5. Accordingly, the stack 16 of FIG. 12 is a stack analogous to that of FIG. 5, and comprises alternating insulative levels 20 and conductive levels 18.

The channel structure 26 may be considered to be within a memory array region 22 analogous to the memory array region described above with reference to FIG. 5, and may be representative of a large number of substantially identical channel structures within such memory array region; with the term “substantially identical” meaning identical to within reasonable tolerances of fabrication and measurement. Thus, the assembly 12 of FIG. 12 may be identical to the assembly 12 shown in FIG. 5. Such assembly 12 may be considered to comprise channel structures 26 extending through the stack 16 and into the material 30 under the stack.

The memory cells 44 (only some of which are labeled) are along the channel structure 26, and are associated with the conductive levels 18. The memory cells 44 along the channel structure 26 may be considered to be vertically stacked one atop another. Each of the memory cells 44 includes regions of the dielectric-barrier material 48, charge-blocking material 50, charge-storage material 52, gate-dielectric material 54 and channel material 56. In some embodiments, the memory cells 44 may be suitable for utilization in NAND, and the vertically-stacked memory cells 44 may be considered to correspond to a string of the memory cells (i.e., a “NAND string”).

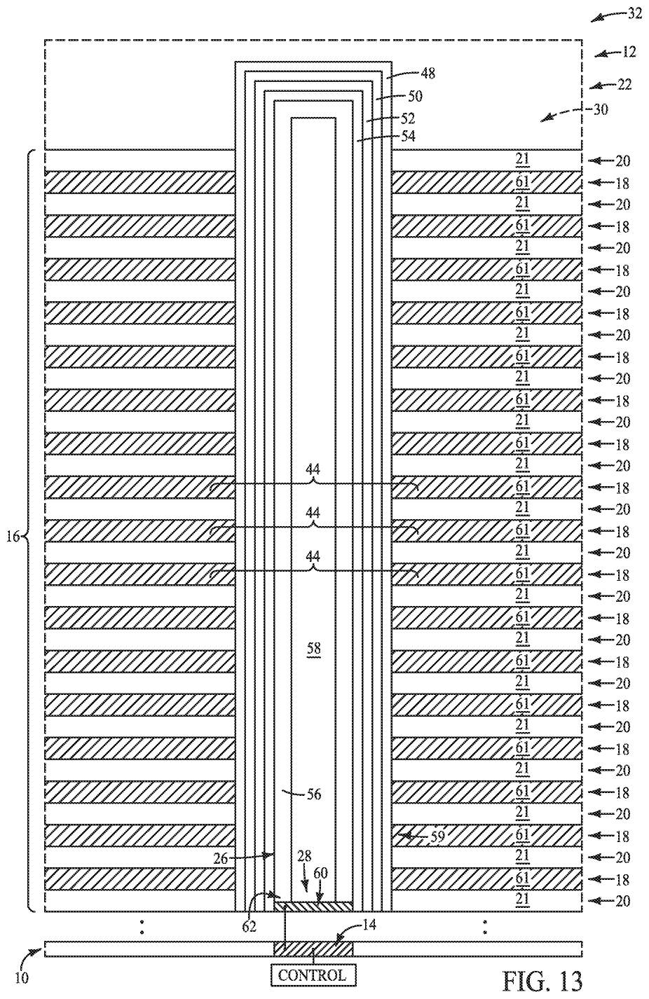

Referring to FIG. 13, the assembly 12 is inverted to form a configuration analogous to that described above with reference to FIG. 6. The inverted configuration may be bonded to another assembly 10 to form the configuration 32. The interconnect 28 of the assembly 12 is bonded with an interconnect 14 of the assembly 10.

The inverted configuration of FIG. 13 has the first material 30 above the stack 16, and has a first region 62 of the channel structure 26 under the lowermost conductive level 18 of stack 16 and electrically coupled with the control circuitry (CONTROL) through the interconnects 14 and 28. The channel structure 26 of FIG. 13 may be representative of a large number of channel structures within the memory array 22 (as shown in FIG. 6), and each of the channel structures may comprise a first region 62 analogous to that shown in FIG. 13. At least some of such first regions may be coupled with the control circuitry (as is diagrammatically illustrated in FIG. 6). The lower region (first region) 62 of the channel structure 26 may be considered to be under the stack 16 if the bottommost conductive level 18 is considered to be a bottom of the stack (i.e., if the bottommost insulative level 20 is not considered to be part of the stack 16).

The material 30 is shown in dashed-line view in FIG. 13 (analogous to the view provided in FIG. 6) to emphasize at least some of the material 30 will be removed.

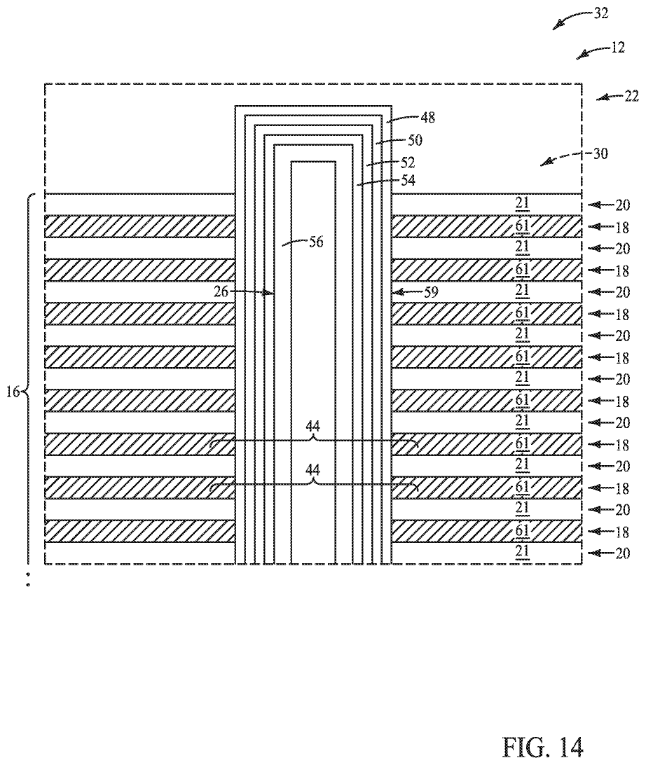

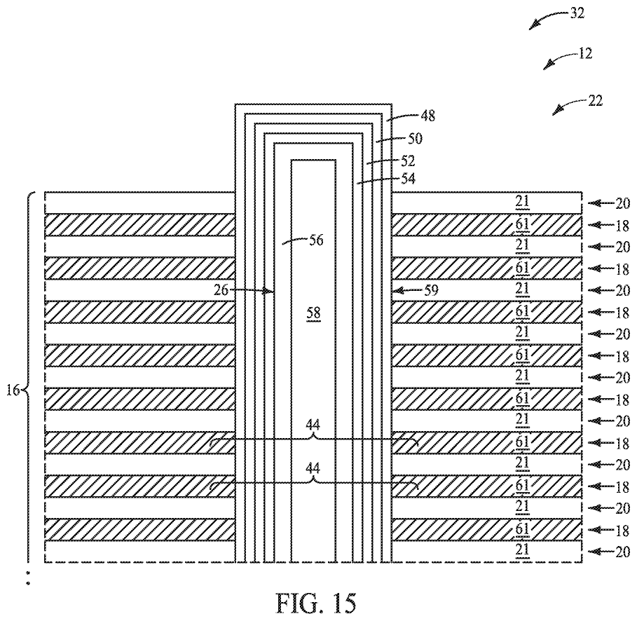

FIG. 14 shows the same configuration as FIG. 13, but only shows an upper portion of the assembly 12. The view of FIG. 14 will be utilized for FIGS. 15-20 of this disclosure to provide sufficient room in the drawings for showing materials formed over the stack 16 at subsequent process stages.

Referring to FIG. 15, the material 30 (FIG. 14) is removed. In the illustrated embodiment, an entirety of the material 30 is removed. Only some of the material 30 may be removed in other embodiments.

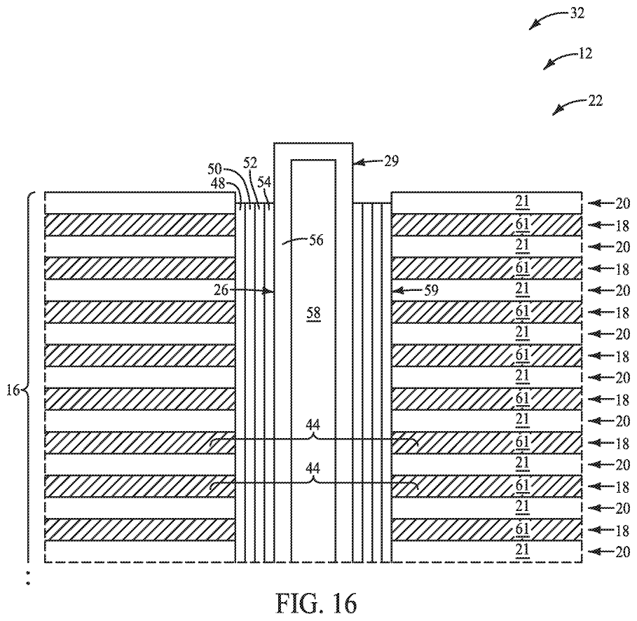

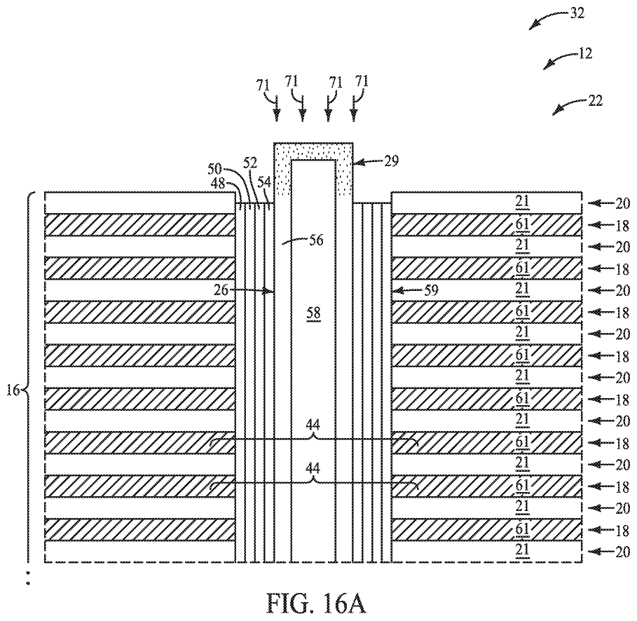

Referring to FIG. 16, upper regions of the materials 48, 50, 52 and 54 are removed to expose the upper region 29 of the channel structure 26. At least some of the exposed upper region 29 is over the stack 16 (i.e., projects to above the stack 16), and in the shown embodiment an entirety of the exposed upper region 29 is over the uppermost conductive level 18 of the stack 16. Such exposed region 29 may be considered to be entirely over the stack 16 if the uppermost conductive level 18 is considered to be a top of the stack (i.e., if the uppermost insulative level 20 is not considered to be part of the stack 16).

The upper region 29 may be referred to as a second region of the channel structure 26 to distinguish it from the first region 62 described above with reference to FIG. 13.

The channel structure 26 of FIG. 16 may be representative of many channel structures formed across the memory array 22, and accordingly the exposed upper region 29 may be representative of many exposed upper regions 29 extending across the memory array 22.

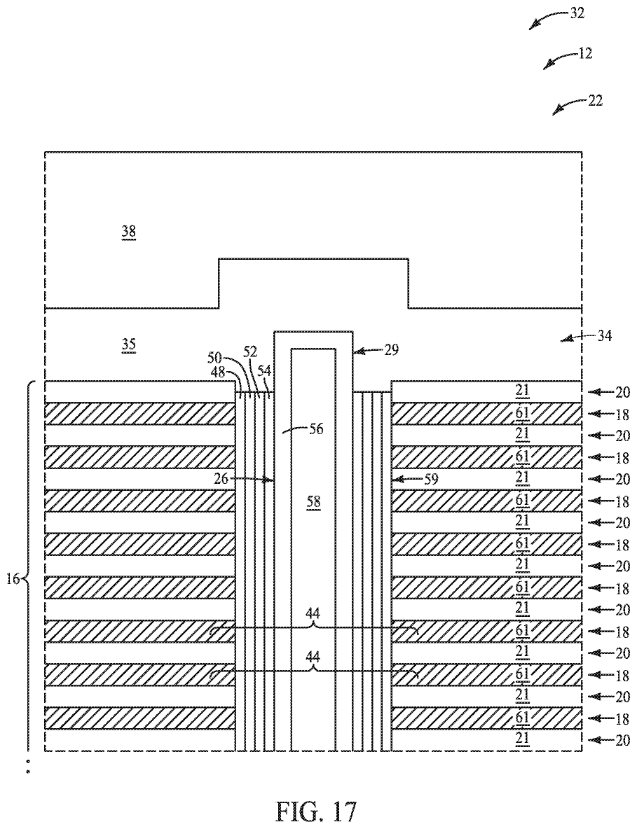

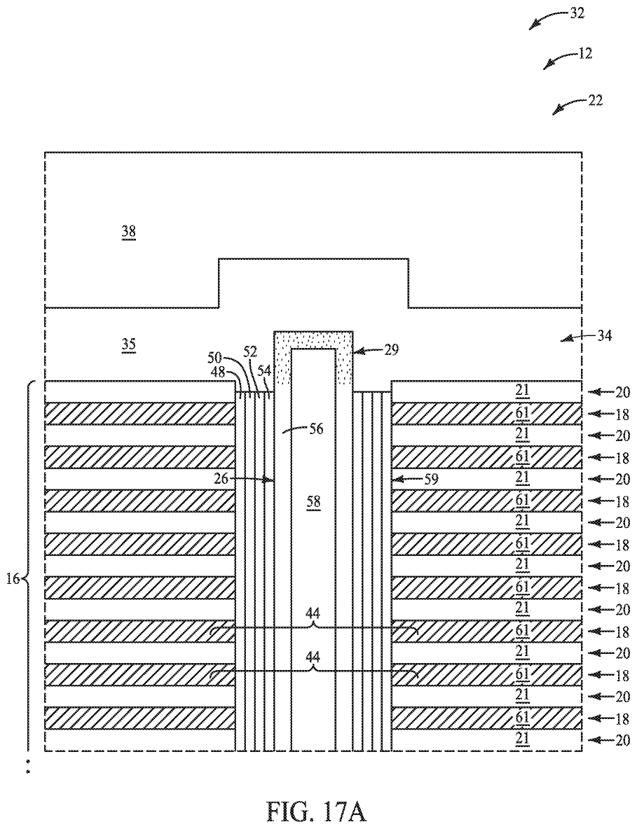

Referring to FIG. 17, the conductive material 35 of structure 34 is formed over the exposed region 29 of the channel structure 26. The material 35 may comprise conductively-doped semiconductor material in some embodiments.

The insulative material 38 (described above with reference to FIG. 8) is formed over the conductively-doped semiconductor material 35.

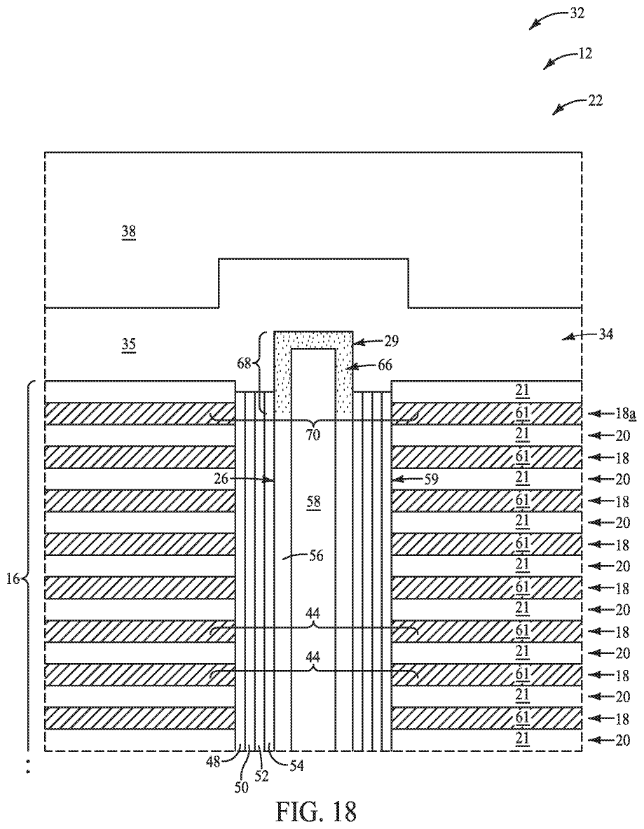

Referring to FIG. 18, dopant 66 (represented by stippling) is out-diffused from the conductively-doped semiconductor material 35 and into the channel material 56 to form a doped region 68 within the channel structure 26.

In some embodiments, the channel material 56 may comprise a first semiconductor material, and the conductively-doped semiconductor material 35 may comprise a second semiconductor material. The first and second semiconductor materials may be the same composition as one another, or may be different compositions relative to one another. In some embodiments, the first and second semiconductor materials may both comprise, consist essentially of, or consist of silicon. The dopant which is out-diffused from the conductively-doped second semiconductor material 35 into the first semiconductor material 56 may be either n-type dopant or p-type dopant. In some embodiments, the out-diffused dopant may be one or more of phosphorus, arsenic, boron, etc. Generally, n-type dopants (e.g., phosphorus and arsenic) are preferred.

The out-diffusion of the dopant may be accomplished with any suitable processing, and in some embodiments may include thermal processing (e.g., processing utilizing a temperature of at least about 300° C., at least about 400° C., etc.). The thermal processing may include rapid thermal processing in some applications. The processing may include a microwave-anneal, a laser-anneal, or any other suitable processing conditions.

In some embodiments, an uppermost of the conductive levels 18 (shown in FIG. 18 as a level 18a) may be a source-side select gate level (SGS level), and may comprise source-select devices (SGS devices) 70. In the shown embodiment, the dopant extends partially across the level 18a to achieve the desired balance between non-leaky OFF characteristics and leaky GIDL characteristics for the SGS devices. In some embodiments, the dopant 66 may be considered to extend downwardly to at least the uppermost conductive level 18a. The dopant may extend partially across such conductive level, or may extend entirely across such conductive level. Although only one of the conductive levels 18 is shown to be incorporated into the source-select devices, in other embodiments multiple conductive levels may be incorporated into the source-select devices. The conductive levels may be electrically coupled with one another (ganged) to be together incorporated into long-channel source-select devices. If multiple of the conductive levels are incorporated into the source-select devices, the out-diffused dopant may extend downwardly across two or more of the conductive levels 18 which are incorporated into the SGS devices.

The embodiment of FIGS. 16-18 assumes that the material 35 comprises conductively-doped semiconductor material. In some embodiments such material may comprise metal (and/or metal-containing compositions) instead of the conductively-doped semiconductor material. In such embodiments, dopant may be implanted into an upper region of the semiconductor material (channel material) 56 as shown in FIG. 16A. The dopant may be, for example, phosphorus or arsenic, and the implant of such dopant is indicated with arrows 71. Stippling is utilized to diagrammatically indicate the dopant within the upper portion of the channel material 56. Subsequently, the metal-containing material 35 may be formed over the doped material 56 as shown in FIG. 17A. The thermal processing described above with reference to FIG. 18 may then be used to disperse the dopant in the same manner as is discussed above with reference to FIG. 18.

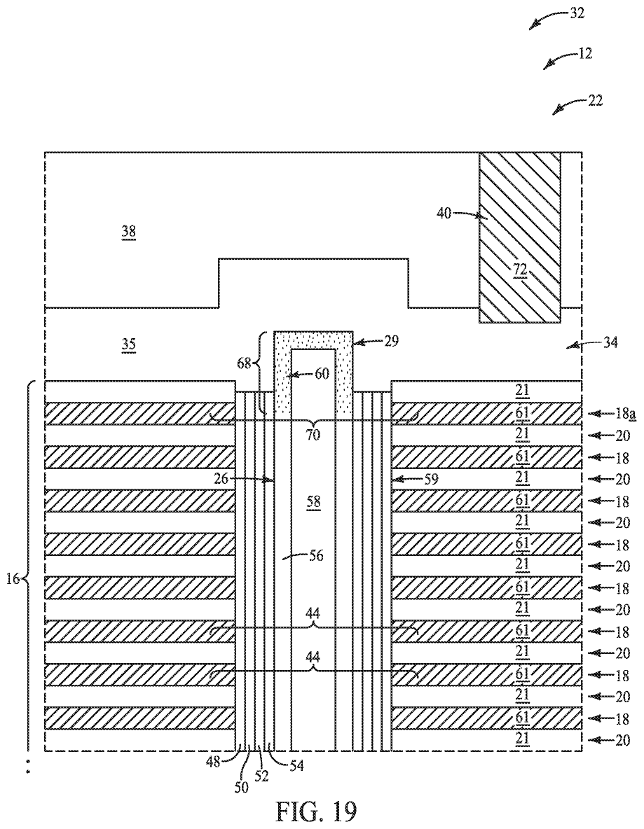

Referring to FIG. 19, a conductive interconnect 40 is formed to extend through the insulative material 38, and to be electrically coupled with the material 35. In the illustrated embodiment, the interconnect 40 penetrates into the material 35. In other embodiments, the interconnect 40 may stop at an upper surface of the material 35 rather than penetrating into such material.

The interconnect 40 comprises a conductive material 72. The conductive material 72 may comprise any suitable electrically conductive composition(s); such as, for example, one or more of various metals (e.g., copper, aluminum, titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.). In some embodiments, the conductive material 72 may be a metal-containing material; and may comprise, for example, one or more of tungsten, tantalum, titanium, titanium nitride, tantalum nitride, titanium silicide, etc. In some embodiments, the material 72 may comprise, consist essentially of, or consist of AlCu, where the formula indicates primary constituents rather than a specific stoichiometry.

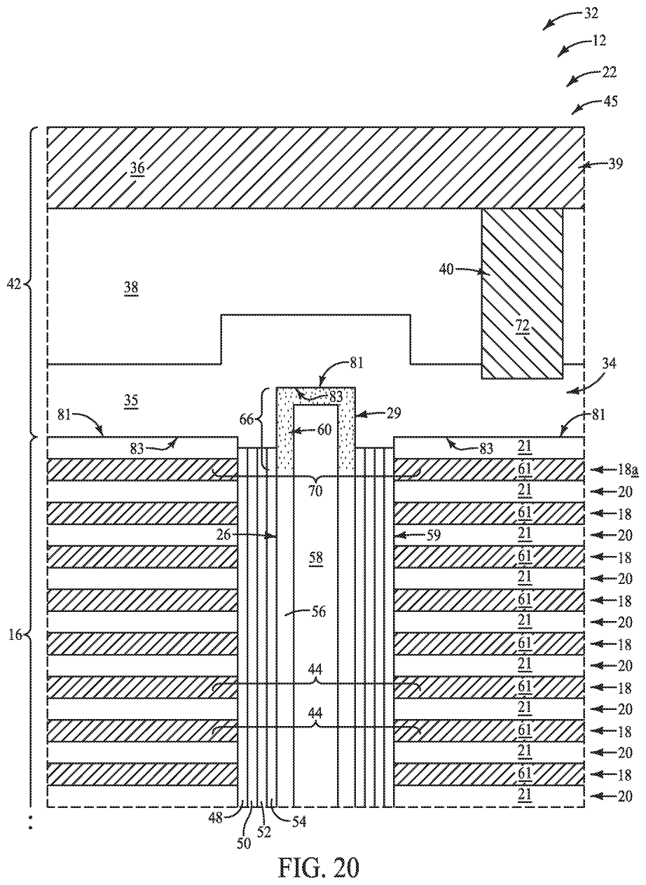

Referring to FIG. 20, the conductive structure 39 is formed over the insulative material 38, and is electrically coupled with the material 35 through the interconnect 40. The conductive structure 39 comprises the conductive material 36 described above with reference to FIG. 8. The assembly 32 of FIG. 20 may be identical to the assembly described above with reference to FIG. 8. The conductive materials 36 and 35 may be incorporated into a source structure 42, and such source structure may be electrically coupled with any suitable voltage source.

The source structure is electrically coupled with the upper regions 29 of the channel structures 26, and in the shown embodiment the material 35 of the source structure is directly against the channel material 56 of the channel structure 26.

The assembly 32 of FIGS. 20 and 8 includes the memory device 45 comprising control circuitry (CONTROL, shown in FIG. 8), and the stack 16 of alternating insulative and conductive levels 20 and 18 over the control circuitry. The channel structures 26 extend through the stack, with the channel structures comprising lower regions 62 (FIG. 8 and FIG. 13) and upper regions 29. At least some of the lower regions 62 of the channel structures 26 are electrically coupled with the control circuitry through bitlines. The upper regions 29 of the channel structures 26 project above the stack 16, and may be considered to define at least a portion of an undulating upper topography 81. The conductive source structure 42 is over the upper regions 29 of the channel structures 26. A lower surface 83 of the conductive source structure 42 (specifically, a lower surface of the material 35) is conformal to the undulating upper topography 81, and is directly against the upper regions 29 of the channel structures 26.

In some embodiments, the upper regions 29 of the channel structures 26 may be considered to penetrate into the conductive source structure 42, and specifically to penetrate into the material 35.

In some embodiments, the conductive material 36 may be considered to extend substantially horizontally along an upper surface of the insulative material 38, and the interconnects 40 may be considered to extend substantially vertically between the conductive material 36 and the conductive material 35.

The embodiments described herein advantageously enable source material to be formed over channel structures. Such may simplify processing as compared to conventional methods which punch openings through stacks of alternating levels and into source material, and then form the channel material to extend through the stacks and into the source material. Further, the embodiments described herein may allow higher stacks to be formed than can be formed by conventional processing, which may reduce a footprint of the stacked memory cells and thereby allow more room for control circuitry (e.g., wordline drivers, etc.). Additionally, the initial formation of the control circuitry along a separate assembly than that utilized for the stack 16 may avoid subjecting the control circuitry to problematic thermal stresses that may be encountered in conventional applications.

The embodiments described herein may simplify formation of the metal-containing material (e.g., material 36) of the source structure (e.g. 42) over the conductive material 35, which may enable the source structure to be formed with improved conductivity (e.g., lower resistance). For instance, the metal-containing material (e.g., material 36) of the source structure may comprise one or both of aluminum and copper.

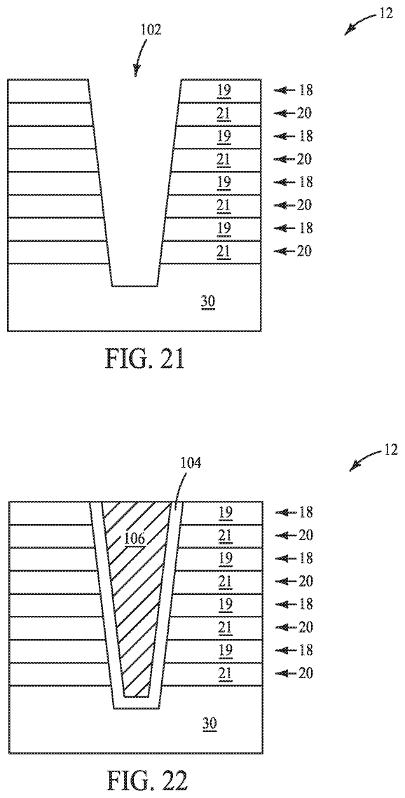

FIG. 8 shows contacts 100 coupled with the material 36 of the global interconnect 39. Such contacts may be fabricated during the process stages associated with the backside punch described above with reference to FIGS. 9-20. An example method for fabricating the contacts 100 is described with reference to FIGS. 21-24.

Referring to FIG. 21, an opening 102 is formed through the layers 18 and 20, and extends into the substrate (e.g., monocrystalline silicon wafer) 30. The process stage of FIG. 21 may be the same as the process stage of FIG. 10.

Referring to FIG. 22, the opening is lined with insulative material 104 (e.g., silicon dioxide) and then is filled with conductive material (e.g., one or more of metal, conductively-doped silicon, metal nitride, metal silicide, etc.) 106. The material 104 may be considered to be configured as an insulative liner at the process stage of FIG. 22, and the conductive material 106 may be considered to be conductive pillar material which is configured as a conductive pillar. The process stage of FIG. 22 may be the same as the process stage of FIG. 11.

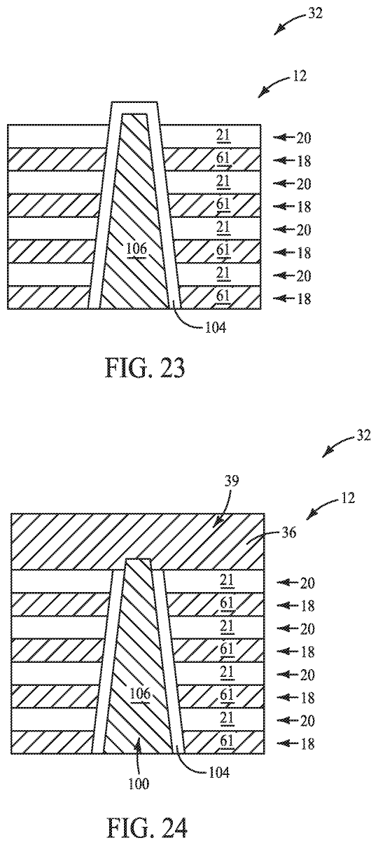

Referring to FIG. 23, the material 19 of the levels 18 is replaced with the conductive material 61, the assembly 12 is inverted, and the substrate 30 is removed. The process stage of FIG. 23 may be the same as the process stage of FIG. 15.

Referring to FIG. 24, the insulative material 104 is removed to expose a region of the conductive material 106, and the material 36 is formed over and in contact with the conductive material 106. Thus, the interconnect 100 is formed. The process stage of FIG. 24 may be the same as the process stage of FIG. 20.

The assemblies and structures discussed above may be utilized within integrated circuits (with the term “integrated circuit” meaning an electronic circuit supported by a semiconductor substrate); and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

Unless specified otherwise, the various materials, substances, compositions, etc. described herein may be formed with any suitable methodologies, either now known or yet to be developed, including, for example, atomic layer deposition (ALD), chemical vapor deposition (CVD), physical vapor deposition (PVD), etc.

The terms “dielectric” and “insulative” may be utilized to describe materials having insulative electrical properties. The terms are considered synonymous in this disclosure. The utilization of the term “dielectric” in some instances, and the term “insulative” (or “electrically insulative”) in other instances, may be to provide language variation within this disclosure to simplify antecedent basis within the claims that follow, and is not utilized to indicate any significant chemical or electrical differences.

The terms “electrically connected” and “electrically coupled” may both be utilized in this disclosure. The terms are considered synonymous. The utilization of one term in some instances and the other in other instances may be to provide language variation within this disclosure to simplify antecedent basis within the claims that follow.

The particular orientation of the various embodiments in the drawings is for illustrative purposes only, and the embodiments may be rotated relative to the shown orientations in some applications. The descriptions provided herein, and the claims that follow, pertain to any structures that have the described relationships between various features, regardless of whether the structures are in the particular orientation of the drawings, or are rotated relative to such orientation.

The cross-sectional views of the accompanying illustrations only show features within the planes of the cross-sections, and do not show materials behind the planes of the cross-sections, unless indicated otherwise, in order to simplify the drawings.

When a structure is referred to above as being “on”, “adjacent” or “against” another structure, it can be directly on the other structure or intervening structures may also be present. In contrast, when a structure is referred to as being “directly on”, “directly adjacent” or “directly against” another structure, there are no intervening structures present. The terms “directly under”, “directly over”, etc., do not indicate direct physical contact (unless expressly stated otherwise), but instead indicate upright alignment.

Structures (e.g., layers, materials, etc.) may be referred to as “extending vertically” to indicate that the structures generally extend upwardly from an underlying base (e.g., substrate). The vertically-extending structures may extend substantially orthogonally relative to an upper surface of the base, or not.

Some embodiments include a method of forming a memory device. An assembly is formed to comprise a stack of alternating insulative and conductive levels over control circuitry. The assembly includes channel structures extending through the stack. The channel structures have upper and lower regions. The upper regions of the channel structures project above the stack. At least some of the lower regions of the channel structures are electrically coupled with the control circuitry. A conductive structure is formed over the upper regions of channel structures and is electrically coupled with the channel structures.

Some embodiments include a method of forming a memory device. An assembly is formed to have channel structures extending through a stack of alternating insulative and conductive levels and into a first material under the stack. The assembly is inverted so that the first material is above the stack, and so that first regions of the channel structures are under the stack. At least some of the first regions are electrically coupled with control circuitry. At least some of the first material is removed, and second regions of the channel structures are exposed. Conductively-doped semiconductor material is formed adjacent the exposed second regions of the channel structures. Dopant is out-diffused from the conductively-doped semiconductor material into the channel structures.

Some embodiments include a memory device comprising control circuitry and a stack of alternating insulative and conductive levels over the control circuitry. Channel structures extend through the stack. The channel structures have upper regions and lower regions. The upper regions of the channel structures project above the stack and define at least a portion of an undulating upper topography. At least some of the lower regions of the channel structures are electrically coupled with the control circuitry. A conductive source structure is over the upper regions of the channel structures. A lower surface of the conductive source structure is conformal to the undulating upper topography and is directly against the upper regions of channel structures.

Some embodiments include a memory device comprising control circuitry and a stack of alternating insulative and conductive levels over the control circuitry. Channel structures extend through the stack. The channel structures have first regions vertically offset from second regions. The second regions of the channel structures project above the stack. At least some of the first regions of the channel structures are electrically coupled with the control circuitry. A conductive source structure is over the second regions of the channel structures. The conductive source structure comprises a conductive material adjacent the second regions of channel structures. The second regions of the channel structures penetrate into the conductive material.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

I/We claim:

1. A method of forming a memory device, comprising:
forming an assembly comprising a stack of alternating insulative and conductive levels over control circuitry; the assembly including channel structures extending through the stack; the channel structures having upper and lower regions; the upper regions of the channel structures projecting above the stack; at least some of the lower regions of the channel structures being electrically coupled with bitlines and the control circuitry; and
forming a conductive structure over the upper regions of channel structures and electrically coupled with the channel structures.

2. The method of claim 1 wherein the electrical coupling to the control circuitry is through the bitlines.

3. The method of claim 1 wherein the conductive structure includes metal.

4. The method of claim 1 wherein the conductive structure includes conductively-doped semiconductor material; and further comprising out-diffusing dopant form the conductively-doped semiconductor material into the channel structures.

5. The method of claim 4 further comprising out-diffusing dopant form the conductively-doped semiconductor material into the channel structures.

6. The method of claim 4 wherein an uppermost of the conductive levels within the stack is a source-side select gate level; and wherein the out-diffused dopant extends downwardly to at least said uppermost of the conductive levels.

7. The method of claim 4 wherein the semiconductor material comprises silicon.

8. The method of claim 4 wherein the channel structures comprise a first semiconductor material, and wherein the semiconductor material of the conductive structure is a second semiconductor material.

9. The method of claim 8 wherein the first and second semiconductor materials comprise a same semiconductor composition as one another.

10. The method of claim 8 wherein the first and second semiconductor materials both comprise silicon.

11. The method of claim 8 wherein the first and second semiconductor materials comprise different semiconductor compositions relative to one another.

12. The method of claim 1 wherein the assembly includes memory cells along at least some of the conductive levels.

13. The method of claim 12 wherein the memory cells include charge-storage material.

14. The method of claim 1 further comprising forming an interconnect which extends through the conductive levels and which is coupled with the conducive structure; the forming of the interconnect comprising:
forming an opening to pass through first and second levels and into a silicon substrate;
forming an insulative liner within the opening;
forming conductive pillar material within the opening, the silicon substrate, insulative liner and conductive pillar material together comprising an assembly;
inverting the assembly;
removing the silicon substrate and removing some of the insulative liner to expose a region of the conductive pillar material; and
forming the conductive structure to directly contact the exposed region of the conductive pillar material.

15. A method of forming a memory device, comprising:
forming an assembly comprising channel structures extending through a stack of alternating insulative and conductive levels and into a first material under the stack;
inverting the assembly so that the first material is above the stack, and so that first regions of the channel structures are under the stack;
electrically coupling at least some of the first regions with control circuitry;
exposing second regions of the channel structures over the stack, the exposure of the second regions comprising removal of the first material; and
forming conductively-doped semiconductor material adjacent the exposed second regions of the channel structures.

16. The method of claim 15 wherein the first material is monocrystalline silicon of a monocrystalline silicon wafer.

17. The method of claim 15 wherein the electrical coupling to the control circuitry is through bitlines.

18. The method of claim 15 wherein the removing of the at least some of the first material removes all of the first material.

19. The method of claim 15 wherein the assembly includes memory cells along at least some of the conductive levels.

20. The method of claim 19 wherein the memory cells include charge-storage material.

21. The method of claim 20 wherein the charge-storage material is a charge-trapping material.

22. The method of claim 15 further comprising forming a conductive structure over the conductively-doped semiconductor material and at least some of the conductive structure being electrically coupled with the conductively-doped semiconductor material; the conductive structure and the conductively-doped semiconductor material together being a source structure.

23. The method of claim 22 further comprising:
forming an insulative material over the conductively-doped semiconductor material;
forming conductive interconnects to extend through the insulative material to the conductively-doped semiconductor material;
forming the conductive structure over the insulative material; and
wherein the electrical coupling of the conductive structure with the conductively-doped semiconductor material extends through the conductive interconnects.

24. The method of claim 22 further comprising out-diffusing dopant from the conductively-doped semiconductor material into the channel structures.

25. The method of claim 24 wherein an uppermost of the conductive levels within the stack is a source-side select gate level; and wherein the out-diffused dopant extends downwardly to at least said uppermost of the conductive levels.

26. The method of claim 15 wherein the channel structures comprise a first semiconductor material, and wherein the conductively-doped semiconductor material is a second semiconductor material.

27. The method of claim 26 wherein the first semiconductor material comprises silicon.

28. The method of claim 26 wherein the first and second semiconductor materials comprise silicon.

29. A memory device, comprising:
control circuitry;
a stack of alternating insulative and conductive levels over the control circuitry;
channel structures extending through the stack; the channel structures having upper regions and lower regions; the upper regions of the channel structures projecting above the stack and defining at least a portion of an undulating upper topography; at least some of the lower regions of the channel structures being electrically coupled with the control circuitry; and
a conductive source structure over the upper regions of the channel structures; a lower surface of the conductive source structure being conformal to the undulating upper topography and being directly against the upper regions of channel structures.

30. The memory device of claim 29 comprising memory cells along at least some of the conductive levels.

31. The memory device of claim 30 wherein the memory cells include charge-storage material.

32. The memory device of claim 31 wherein the charge-storage material includes charge-trapping material.

33. The memory device of claim 32 wherein the charge-trapping material includes silicon nitride.

34. The memory device of claim 29 wherein the conductive source structure comprises a metal-containing material over a conductively-doped semiconductor material.

35. The memory device of claim 34 wherein the conductively-doped semiconductor material comprises silicon.

36. The memory device of claim 34 wherein the metal-containing material is spaced from the conductively-doped semiconductor material by an insulative region; and wherein conductive interconnects pass through the insulative region to electrically couple the metal-containing material with the conductively-doped semiconductor material.

37. The memory device of claim 29 wherein the control circuitry includes CMOS circuitry.

38. A memory device, comprising:
control circuitry;
a stack of alternating insulative and conductive levels over the control circuitry;
channel structures extending through the stack; the channel structures having first regions vertically offset from second regions; the second regions of the channel structures projecting above the stack; at least some of the first regions of the channel structures being electrically coupled with the control circuitry; and
a conductive source structure over the second regions of the channel structures; the conductive source structure comprising a conductive material adjacent the second regions of channel structures; the second regions of the channel structures penetrating into the conductive material.

39. The memory device of claim 38 wherein the conductive material comprises conductively-doped semiconductor material.

40. The memory device of claim 39 wherein the conductively-doped semiconductor material is conductively-doped silicon.

41. The memory device of claim 39 wherein the conductive source structure includes a metal-containing material extending horizontally along the conductively-doped semiconductor material and electrically coupled with the conductively-doped semiconductor material.

42. The memory device of claim 41 wherein the metal-containing material includes one or both of aluminum and copper.

43. The memory device of claim 41 comprising an insulative material between the metal-containing material and the conductively-doped semiconductor material, and comprising conductive interconnects extending through the insulative material; wherein upper surfaces of the conductive interconnects are directly against the metal-containing material; and wherein lower surfaces of the conductive interconnects are directly against the conductively-doped semiconductor material.

44. The memory device of claim 38 comprising memory cells along at least some of the conductive levels.

45. The memory device of claim 44 wherein the memory cells include charge-storage material.

46. The memory device of claim 45 wherein the charge-storage material includes silicon nitride.

47. The memory device of claim 45 wherein an uppermost of the conductive levels within the stack is a source-side select gate level.
